(19) United States
(12) Patent Application Publication
(10) Pub. No.: US 2009/0317976 A1
(43) Pub. Date: Dec. 24, 2009

(54) ETCHING SYSTEM AND METHOD OF MANUFACTURING SEMICONDUCTOR DEVICE

(75) Inventor: Junichi Horie, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/256,019

(22) Filed: Oct. 22, 2008

(30) Foreign Application Priority Data
Jun. 20, 2008 (JP) 2008-161967

(51) Int. Cl. H01L 21/311

(52) U.S. Cl. 438/703; 156/345.48; 257/E21.249

(57) ABSTRACT

An etching system includes: a vacuum chamber; a stage for mounting a workpiece, the stage being disposed within the vacuum chamber; a first electrode located within the vacuum chamber and above the stage; a second located between the first electrode and a ceiling of the vacuum chamber; a gas supply for introducing a process gas into the vacuum chamber; a variable capacitance element connected to the second electrode; and a radio frequency power supply connected to the first electrode and connected through the variable capacitance element to the second electrode. The radio frequency power supply supplies radio frequency power to the first and second electrodes to produce an inductively coupled plasma in the process gas within the vacuum chamber.

### BACKGROUND OF THE INVENTION

1. Field of the Invention

The present invention relates to an inductively coupled plasma (ICP) etching system and a method of manufacturing a semiconductor device using such an etching system.

2. Background Art

In the manufacture of a semiconductor device, a thin film(s) such as an epitaxial layer is dry etched using a patterned resist as a mask. Such dry etching is performed in an etching system which generates an inductively coupled plasma. [See, e.g., Japanese Laid-Open Patent Publication No. 8-316210 (1996).]

### SUMMARY OF THE INVENTION

The electrical characteristics of a semiconductor device depend greatly on the shape of its etched features, e.g., the shape of the edges of the etched layers. However, it has been very difficult to etch a layer or film into a controlled shape, or desired shape, without changing the process conditions, such as the ion energy and the amount of radicals, or without changing the mask material or mask pattern, during the process.

The present invention has been devised to solve the above problems. It is, therefore, an object of the present invention to provide an etching system capable of etching a layer or film into a controlled shape with ease without changing the process conditions and masks. An other object of the present invention is to provide a method of manufacturing a semiconductor device using such an etching system.

According to one aspect of the present invention, an etching system comprises: a vacuum chamber; a stage for mounting a workpiece thereon, said stage being disposed within said vacuum chamber; a first electrode provided within said vacuum chamber and above said stage; a second electrode provided between said first electrode and a ceiling of said vacuum chamber; gas supply means for introducing a process gas into said vacuum chamber; a variable capacitance element connected to said second electrode; and a radio frequency power supply connected to said first electrode and connected through said variable capacitance element to said second electrode; wherein said radio frequency power supply supplies radio frequency power to said first and second electrodes to produce an inductively coupled plasma from said process gas within said vacuum chamber.

Thus, the present invention allows a thin film to be etched into a controlled shape with ease without changing the process conditions and masks.

Other and further objects, features and advantages of the invention will appear more fully from the following description.

### BRIEF DESCRIPTION OF THE DRAWINGS

FIG. 1 is a diagram showing an etching system according to a first embodiment of the present invention.

FIGS. 2-4 are sectional views for explaining a method of manufacturing a semiconductor device according to a first embodiment of the present invention.

FIGS. 5-7 show examples of the shape of the etched ridge.

FIG. 8 is a diagram showing the measured widths of the top and bottom portions of the etched ridges.

FIG. 9 shows the difference between the widths of the top and bottom portions of each ridge.

FIG. 10 is a diagram showing an etching system according to a second embodiment of the present invention.

FIG. 11 is a diagram showing an etching system according to a third embodiment of the present invention.

### DETAILED DESCRIPTION OF THE PREFERRED EMBODIMENTS

### First Embodiment

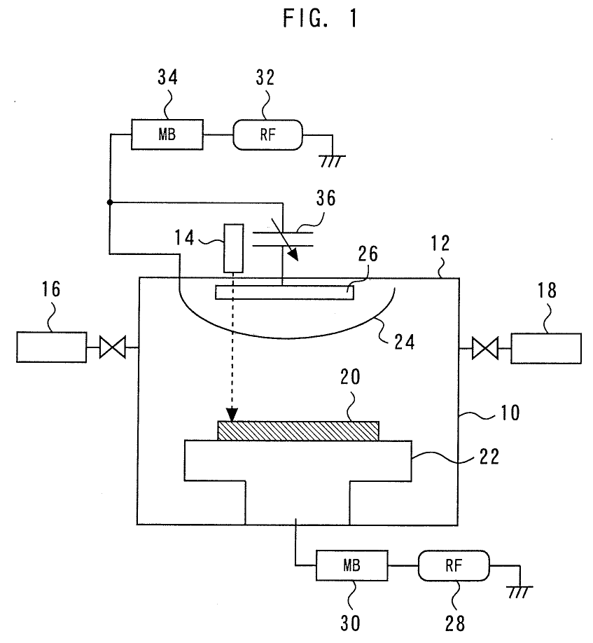

FIG. 1 is a diagram showing an etching system according to a first embodiment of the present invention. In FIG. 1, a vacuum chamber 10 is shown whose ceiling 12 is made of transparent quartz glass. A laser beam interferometric end point detector 14 is provided in the ceiling 12 of the vacuum chamber 10. The vacuum chamber 10 is also provided with gas supply means 16 and gas evacuation means 18 to introduce a process gas into and to evacuate the chamber 10, respectively.

The vacuum chamber 10 contains a stage 22 for mounting a workpiece 20 thereon and also contains an ICP electrode 24 (referred to in the appended claims as a “first electrode”) disposed above the stage 22. Between the ICP electrode 24 and the ceiling 12 of the vacuum chamber 10 is disposed a planar electrode 26 (referred to in the appended claims as a “second electrode”) including a plurality of radially extending antennas.

A radio frequency power supply 28 is connected to the stage 22 through a matching box 30, and a radio frequency power supply 32 is connected to the ICP electrode 24 through a matching box 34. The radio frequency power supply 32 is also connected to the planar electrode 26 through the matching box 34 and a variable capacitor 36 (referred to in the appended claims as a “variable capacitance element”). The capacitance of the variable capacitor 36 can be varied, for example, between 10 pF and 1 F.

The operation of this etching system will now be described. The radio frequency power supply 32 supplies radio frequency (RF) power to the ICP electrode 24 and the planar electrode 26 while the radio frequency power supply 28 supplies RF power to the stage 22, thereby producing inductively coupled plasmas from the process gas within the vacuum chamber 10. The plasma thus produced by the ICP electrode 24 is used to dry etch the workpiece 20. The laser beam interferometric end point detector 14 detects the etching end point in this etching process by means of laser interferometry.

It should be noted that reaction products of the plasma etching attach to the inner walls of the vacuum chamber 10. Especially those attached to the ceiling 12 of the vacuum chamber 10 act to absorb light, thereby preventing the laser beam interferometric end point detector 14 from detecting the etching end point. In order to avoid this, the plasma generated by the planar electrode 26 is used to sputter off, or remove, the attached reaction products from the ceiling 12. The sputtered reaction products then attach to the etched sidewalls of the workpiece 20 again, thus contributing to the formation of the desired shape of the workpiece 20. That is, these sputtered reaction products act to adjust (or reduce) the amount of side etching of the workpiece 20.

It should be noted that changing the capacitance of the variable capacitor 36 results in a change in the power supplied to the planar electrode 26 and hence a change in the amount of reaction products sputtered off from the ceiling 12 of the vacuum chamber 10. This means that the capacitance of the variable capacitor 36 may be varied to etch the workpiece 20 into a controlled shape (or desired shape).

There will now be described a method of manufacturing a semiconductor device according to the present embodiment.

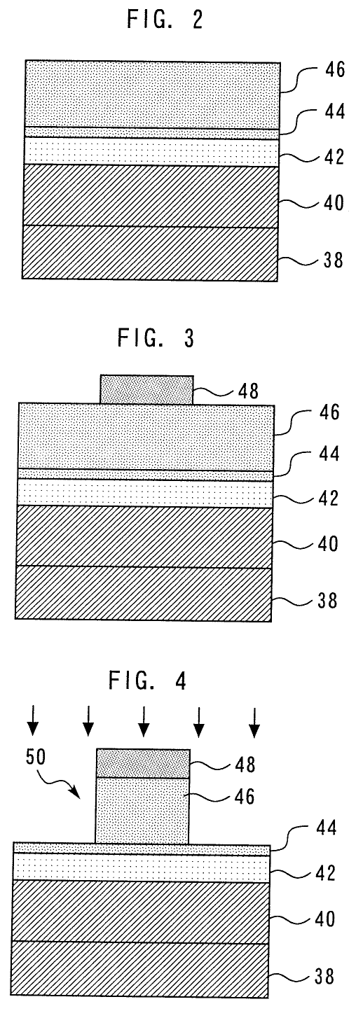

This method begins by sequentially forming an n-AlGaInP cladding layer 40, a multiquantum well active layer 42, an AlGaInP detection layer 44, and a p-AlGaInP cladding layer 46 (referred to in the appended claims as a “thin film”) on top of one another on a GaAs substrate 38 (referred to in the appended claims simply as a “substrate”) by use of an MOCVD or MBE crystal growth apparatus, as shown in FIG. 2.

Next, a resist 48 is formed on the p-AlGaInP cladding layer 46 and patterned by photolithography, etc., as shown in FIG. 3.

Then as shown in FIG. 4, the p-AlGaInP cladding layer 46 is dry etched in the etching system shown in FIG. 1 using the resist 48 as a mask to form a ridge 50. This etching is stopped when the laser beam interferometric endpoint detector 14 detects the AlGaInP detection layer 44. The resist 48 is then removed, and top and bottom electrodes are formed, thereby completing the manufacture of the semiconductor device.

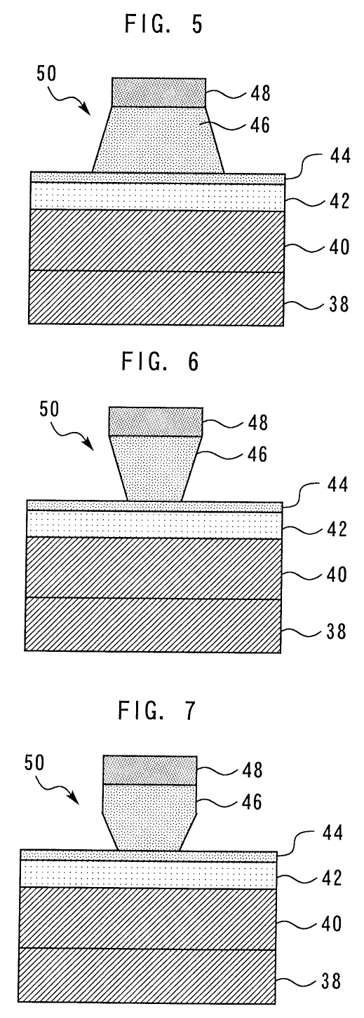

According to the present embodiment, in the above dry etching process, the capacitance of the variable capacitor 36 may be varied to adjust the shape of the ridge 50, namely, the angles of the etched sidewalls of the ridge 50 relative to the surface of the detection layer 44 (or the angles formed by opposing sidewalls of the ridge). More specifically, when the capacitance of the variable capacitor 36 is high, the ridge 50 is formed to a trapezoidal shape in cross section as shown in FIG. 5. When the capacitance is low, on the other hand, the ridge 50 is formed to an inverted trapezoidal shape in cross section as shown in FIG. 6. Further, if the capacitance of the variable capacitor 36 is reduced when the etching process is halfway through, then the ridge 50 assumes across-sectional shape which is a combination of a rectangle and an inverted trapezoid as shown in FIG. 7.

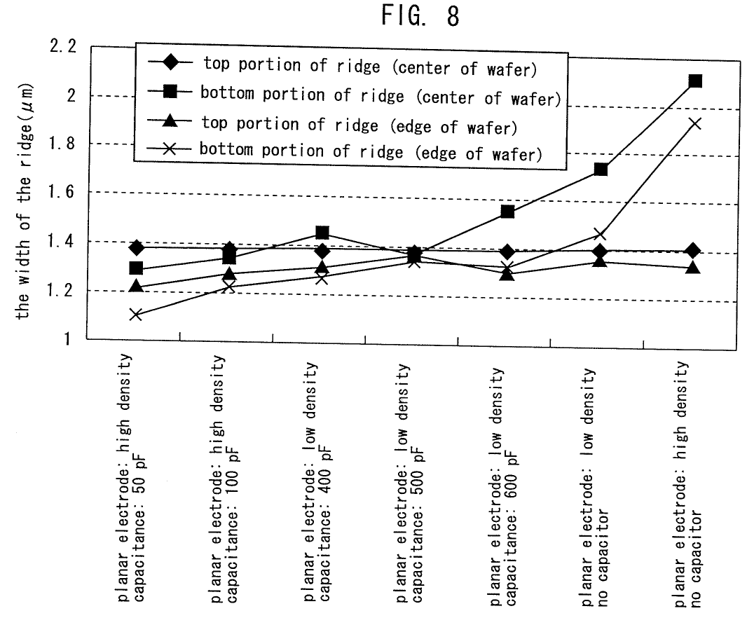

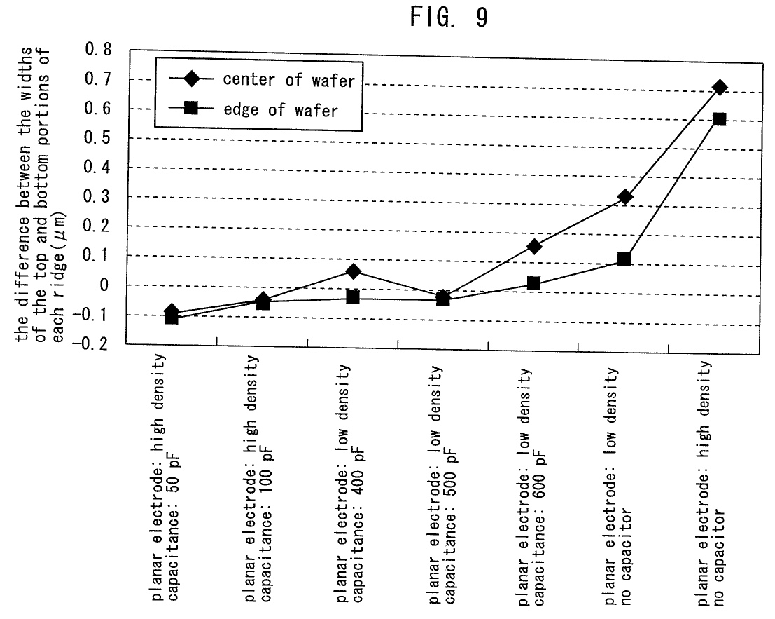

FIG. 8 is a diagram showing the measured widths of the top and bottom portions of the etched ridges of semiconductor devices located at the center and near the edge of a wafer when the etching system did and did not have a variable capacitor, and when the planar electrode of the etching system was made up of a large number of closely spaced antennas and when it was made up of a small number of significantly spaced antennas. The capacitance of the variable capacitor was set at five different values, namely, 50 pF, 100 pF, 400 pF, 500 pF, and 600 pF. FIG. 9 shows the difference between the widths of the top and bottom portions of each ridge (i.e., the bottom width minus the top width). These figures indicate that the capacitance of the variable capacitor of the etching system may be varied to adjust the shape of the ridge of a semiconductor device when the ridge is formed by etching in the system.

As described above, in the manufacture of a semiconductor device the present embodiment allows a layer or thin film to be etched into a ridge of a controlled shape with ease without changing the process conditions and masks. Accordingly, since the electrical characteristics of the semiconductor device depend on the angles of the sidewalls of the ridge relative to the surface of the underlying detection layer (or the angles formed by opposing sidewalls of the ridge), the ridge may be formed by etching to such a shape that the semiconductor device has the desired electrical characteristics.

### Second Embodiment

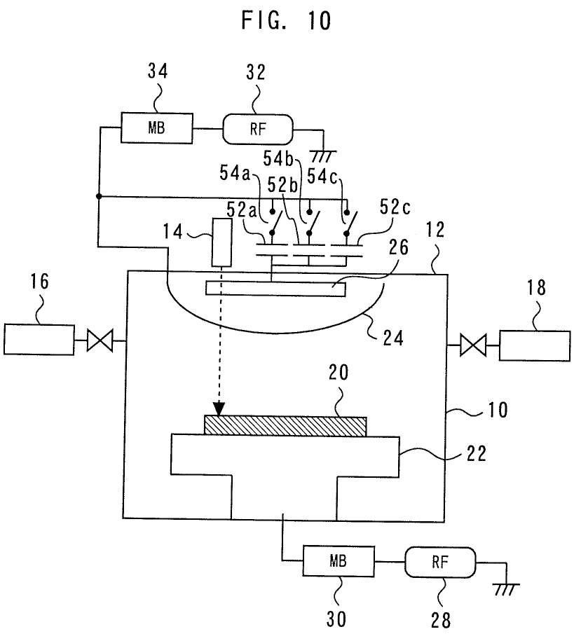

FIG. 10 is a diagram showing an etching system according to a second embodiment of the present invention. This etching system differs from that of the first embodiment in that the variable capacitor 36 is replaced by a variable capacitance element made up of a plurality of parallel-connected fixed capacitances 52a, 52b, and 52c and a plurality of switches 54a, 54b, and 54c connected in series to the capacitances 52a, 52b, and 52c, respectively. All other components are the same as in the first embodiment. That is, the total capacitance of the variable capacitance element can be varied by selectively switching the switches 54a, 54b, and 54c, resulting in the same advantages as described above in connection with the first embodiment.

### Third Embodiment

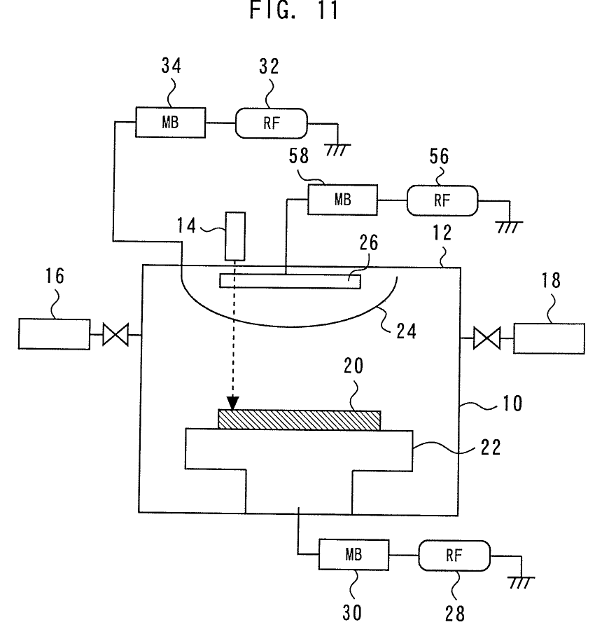

FIG. 11 is a diagram showing an etching system according to a third embodiment of the present invention. This etching system is constructed as follows. A radio frequency power supply 32 (referred to in the appended claims as a “first radio frequency power supply”) is connected to the ICP electrode 24 through a matching box 34, and a radio frequency power supply 56 (referred to in the appended claims as a “second radio frequency power supply”) is connected to the planar electrode 26 through a matching box 58. The radio frequency power supplies 28, 32, and 56 supply RF power to the stage 22, the ICP electrode 24, and the planar electrode 26, respectively, thereby producing inductively coupled plasmas from the process gas within the vacuum chamber 10. Other components perform the same functions as those described in connection with the first embodiment. This arrangement allows the workpiece 20 to be etched into a controlled shape by varying the RF power supplied from the radio frequency power supply 56 to the planar electrode 26, thereby ensuring the advantages described above in connection with the first embodiment.

Thus, according to the method of the present embodiment for manufacturing a semiconductor device, the workpiece 20 can be etched into a controlled shape by adjusting the RF power supplied from the radio frequency power supply 56 to the planar electrode 26. Except for this feature the present embodiment is similar to the first embodiment and hence retains the advantages of the first embodiment.

Although preferred embodiments of the present invention have been described in connection with the manufacture of a GaAs-based compound semiconductor device, it is to be understood that the invention may be applied to the manufacture of GaN-based and In P-based compound semiconductor devices and to etching insulating films.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2008-161967, filed on Jun. 20, 2008 including specification, claims, drawings and summary, on which the Convention priority of the present application is based, are incorporated herein by reference in its entirety.

1. An etching system comprising:
a vacuum chamber;
a stage for mounting a workpiece thereon, said stage being disposed within said vacuum chamber;
a first electrode located within said vacuum chamber and above said stage;
a second electrode located between said first electrode and a ceiling of said vacuum chamber;
gas supply means for introducing a process gas into said vacuum chamber;
a variable capacitance element connected to said second electrode; and
a radio frequency power supply connected to said first electrode and connected through said variable capacitance element to said second electrode, wherein said radio frequency power supply supplies radio frequency power to said first and second electrodes to produce an inductively coupled plasma in the process gas within said vacuum chamber.

2. An etching system comprising:
a vacuum chamber;
a stage for mounting a workpiece thereon, said stage being disposed within said vacuum chamber;
a first electrode located within said vacuum chamber and above said stage;
a second electrode located between said first electrode and a ceiling of said vacuum chamber;
gas supply means for introducing a process gas into said vacuum chamber;
a first radio frequency power supply connected to said first electrode; and
a second radio frequency power supply connected to said second electrode, wherein said first and second radio frequency power supplies supply radio frequency power to said first and second electrodes, respectively, to produce an inductively coupled plasma in the process gas within said vacuum chamber.

3. A method of manufacturing a semiconductor device, comprising:
providing a substrate;
forming a thin film on said substrate;
forming a resist on said thin film and patterning said resist;
dry etching said thin film by use of the etching system as claimed in claim 1, using said resist as a mask; and
varying the capacitance of said variable capacitance element of said etching system to etch said thin film into a controlled shape.

4. A method of manufacturing a semiconductor device, comprising:
providing a substrate;
forming a thin film on said substrate;
forming a resist on said thin film and patterning said resist;
dry etching said thin film by use of the etching system as claimed in claim 2, using said resist as a mask; and
varying the radio frequency power supplied from said second radio frequency power supply to said second electrode to etch said thin film into a controlled shape.
